(19) United States
(12) Patent Application Publication
(10) Pub. No.: US 2021/0280507 A1
(43) Pub. Date: Sep. 9, 2021

(54) PACKAGE COMPRISING DUMMY INTERCONNECTS

(71) Applicant: QUALCOMM Incorporated, San Diego, CA (US)

(72) Inventors: Manuel ALDRETE, Encinitas, CA (US); Milind SHAH, San Diego, CA (US); Srikanth KULKARNI, San Diego, CA (US)

(21) Appl. No.: 16/810,589

(22) Filed: Mar. 5, 2020

(51) Int. Cl. H01L 23/498; H01L 23/31; H01L 23/64; H01L 21/56; H01L 21/48

(52) U.S. Cl. CPC H01L 23/49861; H01L 23/3121; H01L 21/4846; H01L 23/64; H01L 21/56; H01L 23/49816

(57) ABSTRACT

A package comprising a substrate comprising a first surface and a second surface, a passive device coupled to the first surface of the substrate, a first encapsulation layer located over the first surface of the substrate, wherein the first encapsulation layer encapsulates the passive device, an integrated device coupled to the second surface of the substrate, a second encapsulation layer located over the second surface of the substrate, wherein the second encapsulation layer encapsulates the integrated device, a plurality of through encapsulation layer interconnects coupled to the substrate, a plurality of encapsulation layer interconnects coupled to the plurality of through encapsulation layer interconnects, and at least one dummy interconnect located in the second encapsulation layer, wherein the at least one dummy interconnect is located vertically over a back side of the integrated device.

### FIELD

Various features relate to packages that include an integrated device, but more specifically to a package that includes an integrated device and dummy interconnects.

### BACKGROUND

FIG. 1 illustrates a package 100 that includes a substrate 102, an integrated device 104, a passive device 106, and an encapsulation layer 108. The substrate 102 includes a plurality of dielectric layers 120, a plurality of interconnects 122, and a plurality of solder interconnects 124. A plurality of solder interconnects 144 is coupled to the substrate 102 and the integrated device 104. The encapsulation layer 108 encapsulates the integrated device 104, the passive device 106 and the plurality of solder interconnects 144. An integrated device 130 may be coupled to a bottom side of the substrate 102, through the plurality of solder interconnects 132. The package 100 may be subject to a lot of stress (e.g., shear stress, mechanical stress) when the package 100 is coupled to a board, which can affect the reliability of the package 100. There is an ongoing need to provide more reliable packages.

### SUMMARY

Various features relate to packages that include an integrated device, but more specifically to a package that includes an integrated device and dummy interconnects.

One example provides a package comprising a substrate comprising a first surface and a second surface, a passive device coupled to the first surface of the substrate, a first encapsulation layer located over the first surface of the substrate, wherein the first encapsulation layer encapsulates the passive device, an integrated device coupled to the second surface of the substrate, a second encapsulation layer located over the second surface of the substrate, wherein the second encapsulation layer encapsulates the integrated device, a plurality of through encapsulation layer interconnects coupled to the substrate, a plurality of encapsulation layer interconnects coupled to the plurality of through encapsulation layer interconnects, and at least one dummy interconnect located in the second encapsulation layer, wherein the at least one dummy interconnect is located vertically over a back side of the integrated device.

Another example provides an apparatus comprising a substrate, a passive device, first means for encapsulation, an integrated device, second means for encapsulation, a plurality of through encapsulation layer interconnects, and at least one dummy interconnect. The substrate includes a first surface and a second surface. The substrate further comprises a plurality of interconnects. The passive device is coupled to the first surface of the substrate. The first means for encapsulation located over the first surface of the substrate, where the first means for encapsulation encapsulates the passive device. The integrated device is coupled to the second surface of the substrate. The second means for encapsulation is located over the second surface of the substrate, where the second means for encapsulation encapsulates the integrated device. The plurality of through encapsulation layer interconnects is coupled to the substrate. The plurality of encapsulation layer interconnects is coupled to the plurality of through encapsulation layer interconnects. The at least one dummy interconnect is located in the second encapsulation layer, where the at least one dummy interconnect is located vertically over a back side of the integrated device.

Another example provides a method for fabricating a package. The method provides a substrate comprising a first surface and a second surface, where the substrate further comprises a plurality of interconnects. The method couples a passive device to the first surface of the substrate. The method forms a first encapsulation layer over the first surface of the substrate, where the first encapsulation layer encapsulates the passive device. The method couples an integrated device to the second surface of the substrate. The method provides a plurality of through encapsulation layer interconnects to the substrate. The method forms a second encapsulation layer over the second surface of the substrate, where the second encapsulation layer encapsulates the integrated device. The method provides a plurality of encapsulation layer interconnects to the plurality of through encapsulation layer interconnects. The method provides at least one dummy interconnect in the second encapsulation layer, where the at least one dummy interconnect is located vertically over a back side of the integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile view of a package that includes an integrated device and a substrate.

FIG. 2 illustrates a profile view of a package that includes a substrate, an integrated device, an encapsulation layer and at least one dummy interconnect.

FIG. 3 illustrates a bottom plan view of a package that includes an encapsulation layer, at least one dummy interconnect, and at least one dummy solder interconnect.

FIG. 4 illustrates a profile view of a package that includes a substrate, an integrated device, an encapsulation layer and at least one dummy interconnect.

FIG. 5 illustrates a profile view of a package that includes a substrate, an integrated device, an encapsulation layer and at least one dummy interconnect.

FIG. 6 illustrates a profile view of a package that includes a substrate, an integrated device, an encapsulation layer and at least one dummy interconnect.

FIG. 7 (comprising FIGS. 7A-7F) illustrates an exemplary sequence for fabricating a package that includes a substrate, an integrated device, an encapsulation layer and at least one dummy interconnect.

FIG. 8 illustrates an exemplary flow diagram of a method for fabricating a package that includes a substrate, an integrated device, an encapsulation layer and at least one dummy interconnect.

FIG. 9 (comprising FIGS. 9A-9C) illustrates an exemplary sequence for fabricating a package that includes a substrate, an integrated device, an encapsulation layer and at least one dummy interconnect.

FIG. 10 illustrates an exemplary flow diagram of a method for fabricating a package that includes a substrate, an integrated device, an encapsulation layer and at least one dummy interconnect.

FIG. 11 illustrates various electronic devices that may integrate a die, an integrated device, an integrated passive device (IPD), a passive component, a package, and/or a device package described herein.

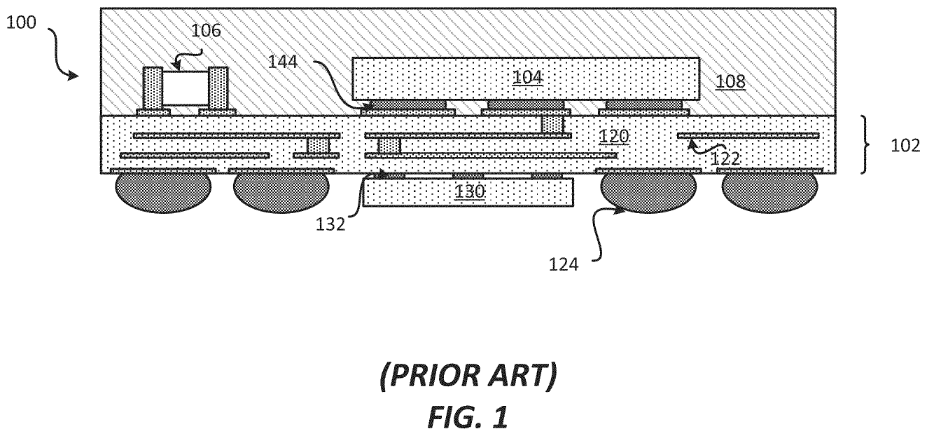

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a substrate, a first encapsulation layer, a second encapsulation layer, an integrated device and a passive device. The substrate includes a plurality of interconnects. The substrate further includes a first surface and a second surface. The passive device is coupled to the first surface of the substrate. A first encapsulation layer is located over the first surface of the substrate. The first encapsulation layer encapsulates the passive device. The integrated device is coupled to the second surface of the substrate. The second encapsulation layer is located over the second surface of the substrate. The second encapsulation layer encapsulates the integrated device. The package further includes (i) a plurality of through encapsulation layer interconnects coupled to the substrate, (ii) a plurality of encapsulation layer interconnects coupled to the plurality of through encapsulation layer interconnects, and (iii) at least one dummy interconnect located in the second encapsulation layer. The at least one dummy interconnect is located vertically over a back side of the integrated device. The at least one dummy interconnect is configured to be free of an electrical connection with the integrated device. The at least one dummy interconnect is configured to be free of an electrical connection with the passive device. The at least one dummy interconnect helps provide structural support for the package, when the package is coupled to a board, which may help provide a more reliable package. Moreover, the at least one dummy interconnect may help with dissipating heat away from the integrated device, which may help with the performance of the integrated device.

### Exemplary Package Comprising Dummy Interconnects

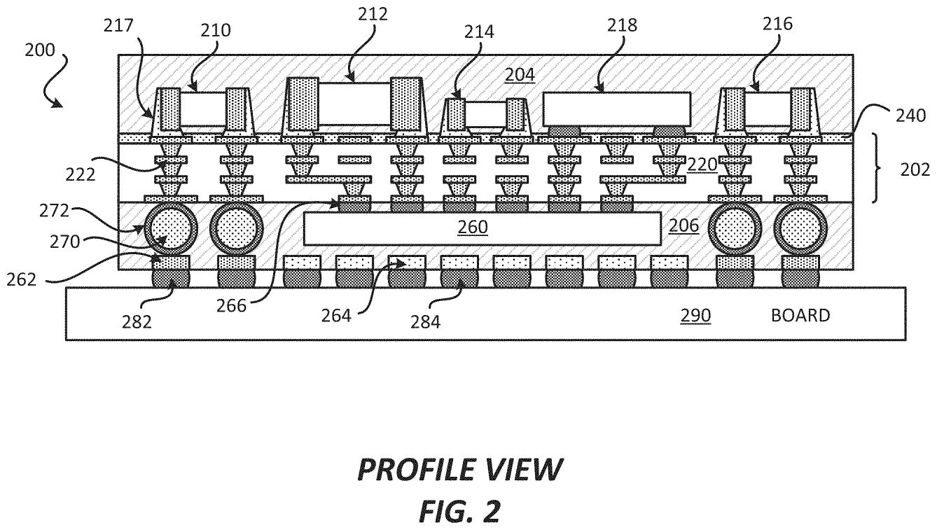

FIG. 2 illustrates a profile view of a package 200 that includes dummy interconnects. The package 200 is coupled to a board 290 (e.g., printed circuit board). As will be further described below, the dummy interconnects help provide additional mechanical support for the package to provide board (e.g., printed circuit board (PCB)) level reliability and to provide improved heat dissipation capabilities for the package 200.

The package 200 includes a substrate 202, a first encapsulation layer 204, a second encapsulation layer 206, an integrated device 260, a plurality of passive devices (e.g., 210, 212, 214, 216) and an integrated device 218. The substrate 202 includes at least one dielectric layer 220 and a plurality of interconnects 222. The substrate 202 2 further includes a first surface and a second surface. The passive devices (e.g., 210, 212, 214, 216) and the integrated device 218 are coupled to the first surface of the substrate 202 (e.g., through their respective solder interconnects 217). The first encapsulation layer 204 is located over the first surface of the substrate 202. The first encapsulation layer 204 encapsulates the passive devices (e.g., 210, 212, 214, 216) and the integrated device 218. A solder resist layer 240 may be located over the first surface of the substrate 202. The solder resist layer 240 may be considered part of the substrate 202. The solder resist layer 240 may be located between the first encapsulation layer 204 and the at least one dielectric layer 220. Another integrated device 260 is coupled to the second surface of the substrate 202. For example, a front side of the integrated device 260 may be coupled to the second surface of the substrate 202. The second encapsulation layer 206 is located over the second surface of the substrate 202. The second encapsulation layer 206 encapsulates the integrated device 260.

The package 200 also includes (i) a plurality of ball interconnects 270 coupled to the substrate 202, (ii) a plurality of encapsulation layer interconnects 262 coupled to the plurality of ball interconnects 270, and (iii) at least one dummy interconnect 264 located in the second encapsulation layer 206.

The plurality of ball interconnects 270 may include a plurality of solder interconnects 272. The plurality of solder interconnects 272 may help the ball interconnects 270 couple to the plurality of interconnects 222 and the plurality of encapsulation layer interconnects 262. In some implementations, the plurality of ball interconnects 270 and the plurality of solder interconnects 272 are an example of a plurality of through encapsulation layer interconnects coupled to the substrate 202. Thus, FIG. 2 may illustrate a package 200 that includes (i) a plurality of through encapsulation layer interconnects coupled to the substrate 202, and (ii) a plurality of encapsulation layer interconnects 262 coupled to the plurality of through encapsulation layer interconnects.

The at least one dummy interconnect 264 is located vertically over a back side of the integrated device 260. The at least one dummy interconnect 264 is configured to be free of an electrical connection with integrated device(s) of the package 200. The at least one dummy interconnect 264 is configured to be free of an electrical connection with the passive device(s) of the package 200. The at least on dummy interconnect 264 may help provide mechanical support for the package 200 by increasing the surface area through which stress (e.g., mechanical stress, thermal stress) on the package 200 is applied on. Increasing the surface area of the coupling of the package 200 to the board 290 helps spread out the stress, and helps decrease stress at specific points of coupling between the package 200 and the board 290, leading to a more reliable joint connection between the package 200 and the board 290 and ultimately a more reliable package.

Moreover, the at least one dummy interconnect 264 may help with heat dissipation of the package 200. For example, the at least one dummy interconnect 264 is located closely to (or may be touching) the integrated device 260. Since the at least one dummy interconnect 264 has a higher thermal conductivity value than the thermal conductivity value of the second encapsulation layer 206, the at least one dummy interconnect 264 may be configured as a heat sink and/or heat spreader for the integrated device 260 and/or the package 200. The at least one dummy interconnect 264 may include the same material or different material than the plurality of encapsulation layer interconnects 262.

Different implementations may have different numbers of dummy interconnects. The at least one dummy interconnect 264 may have different shapes and/or sizes. In some implementations, the at least one dummy interconnect 264 may be coupled to the back side of the integrated device 260.

The package 200 is coupled to the board 290 through a plurality of solder interconnects 282 and a plurality of solder interconnects 284. The plurality of solder interconnects 282 is coupled to the plurality of encapsulation layer interconnects 262. The plurality of solder interconnects 284 is coupled to the at least one dummy interconnects. The plurality of solder interconnects 284 may be considered a plurality of dummy solder interconnects.

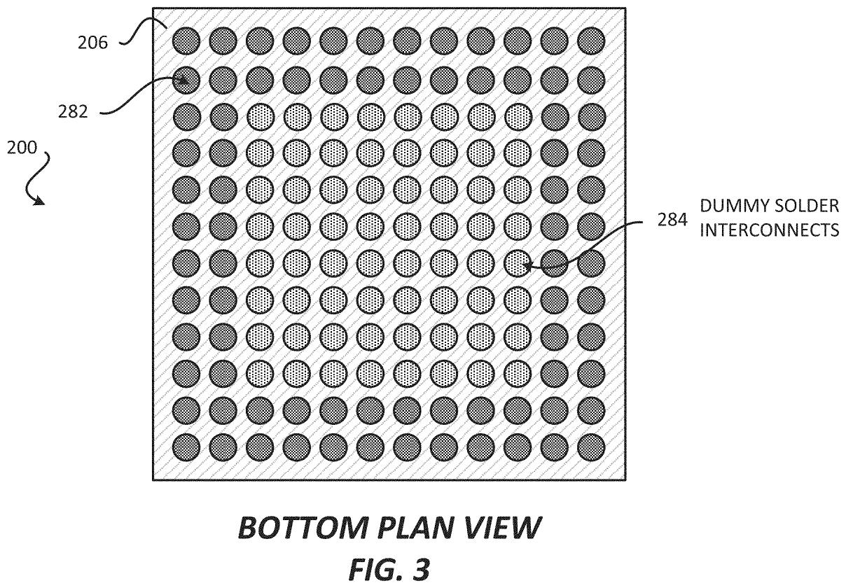

FIG. 3 illustrates a bottom plan view of the package 200. As shown in FIG. 3, the package 200 includes the second encapsulation layer 206, the plurality of solder interconnects 282 and the plurality of solder interconnects 284. The plurality of solder interconnects 284 may be a plurality of dummy solder interconnects. The plurality of dummy solder interconnects (e.g., 284) is configured to be free of an electrical connection with integrated device(s) of the package 200. The plurality of dummy solder interconnects (e.g., 284) is configured to be free of an electrical connection with the passive device(s) of the package 200. Similar to the dummy interconnect 264, the plurality of dummy solder interconnects 284 helps provide mechanical support for the package 200 and helps dissipate heat away from the package 200 and/or integrated devices in the package 200. FIG. 3 illustrates that the plurality of solder interconnects 282 laterally surrounds the plurality of solder interconnects 284. The plurality of solder interconnects 282 may be located along a periphery of the package 200, while the plurality of solder interconnects 284 may be located around an inner portion of the package 200.

It is noted that different implementation may include different configurations of the package 200. For example, different implementations of the package 200 may include different numbers of integrated devices and/or passive devices. For example, the package 200 may include more than one integrated device that is coupled to the second surface of the substrate 202. In another example, one or more passive devices may be coupled to the second surface of the substrate 202.

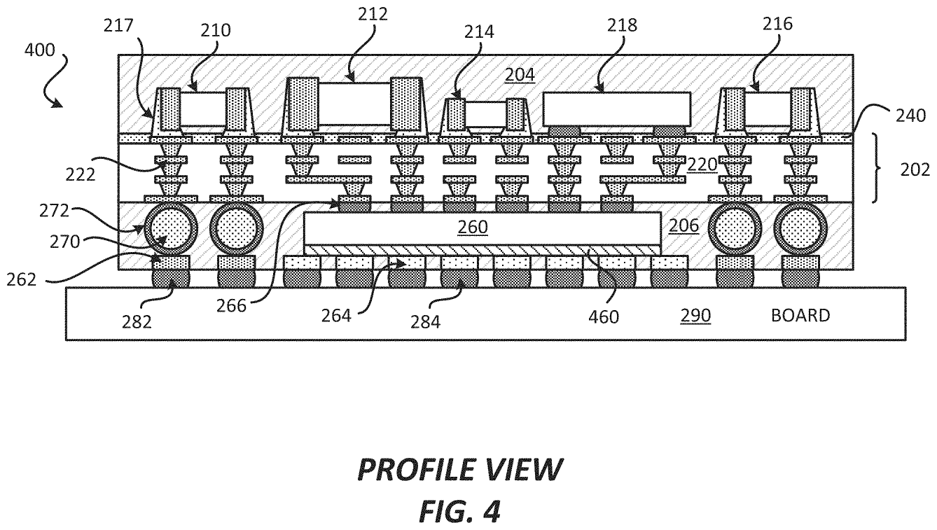

FIG. 4 illustrates a package 400 that includes dummy interconnects. The package 400 is similar to the package 200, and thus includes similar components as the package 200. The package 400 includes a thermal interface material (TIM) 460. The TIM 460 is coupled to the back side of the integrated device 260 and the at least one dummy interconnect 264. The TIM 460 is encapsulated by the second encapsulation layer 206. The TIM 460 has better (e.g., higher) thermal conductivity value than the thermal conductivity value of the second encapsulation layer 206. The TIM 460 with the at least one dummy interconnect 264 may help provide better heat dissipation for the package 200 and/or the integrated device 260 than the at least one dummy interconnect 264 without the TIM 460.

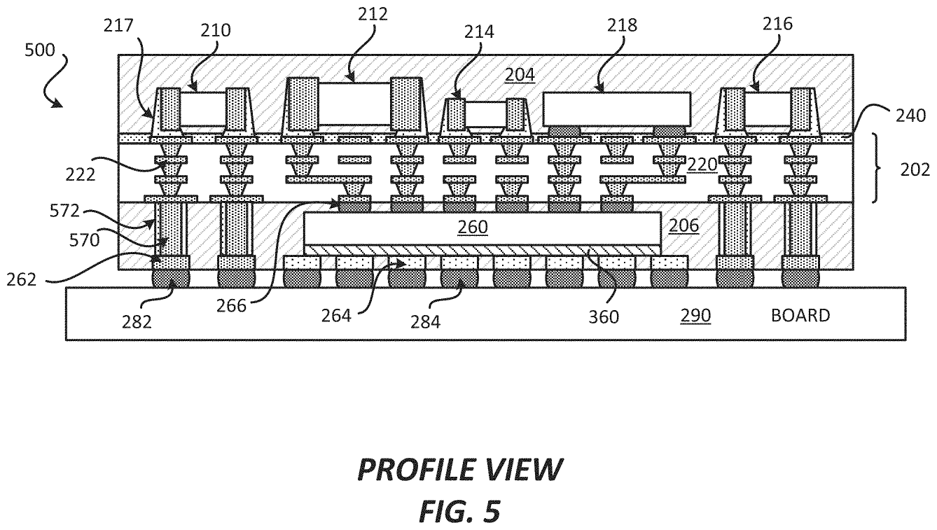

FIG. 5 illustrates a package 500 that includes dummy interconnects. The package 500 is similar to the package 200 and/or the package 400, and thus includes similar components as the package 200 and/or the package 400. The package 500 includes a different through encapsulation layer interconnects. Instead of the plurality of ball interconnects 270, the package 500 includes a plurality of vias 570 and a dielectric layer 572. The dielectric layer 572 may laterally surround the plurality of vias 570. The plurality of vias 570 may be considered a plurality of pillars. The plurality of vias 570 and the dielectric layer 572 may be encapsulated by the second encapsulation layer 206. The plurality of vias 570 is coupled to the substrate 202 and the plurality of encapsulation layer interconnects 262.

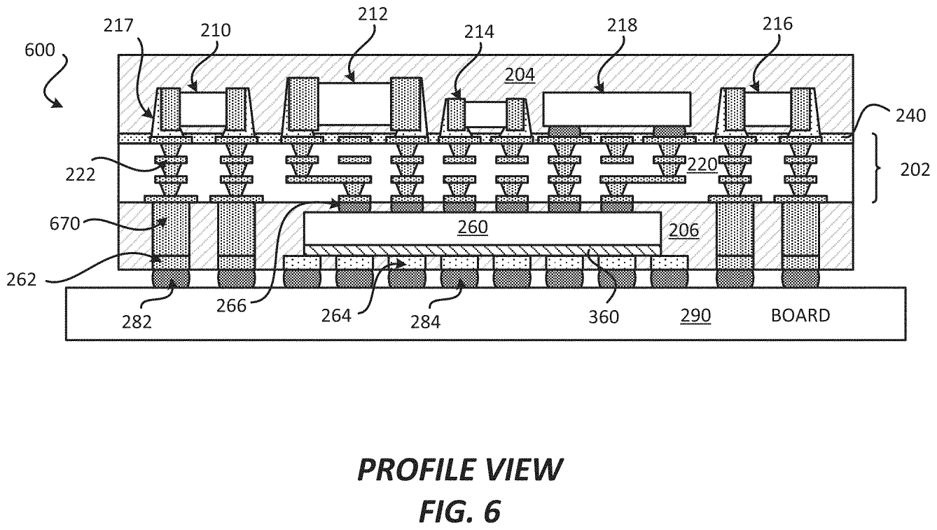

FIG. 6 illustrates a package 600 that includes dummy interconnects. The package 600 is similar to the package 200 and/or the package 400, and thus includes similar components as the package 200 and/or the package 400. The package 600 includes a different through encapsulation layer interconnects. Instead of the plurality of ball interconnects 270, the package 600 includes a plurality of vias 670. The plurality of vias 670 may be encapsulated by the second encapsulation layer 206. The plurality of vias 670 is coupled to the substrate 202 and the plurality of encapsulation layer interconnects 262. The plurality of vias 670 and the plurality of encapsulation layer interconnects 262 may be considered the same. As will be further describe below, the plurality of vias 670 may be formed using a plating process and/or sputtering process.

An integrated device (e.g., 218, 260) may include a die (e.g., semiconductor bare die). The integrated device may include a radio frequency (RF) device, a passive device, a filter, a capacitor, an inductor, an antenna, a transmitter, a receiver, a surface acoustic wave (SAW) filters, a bulk acoustic wave (BAW) filter, a light emitting diode (LED) integrated device, a silicon carbide (SiC) based integrated device, and/or combinations thereof.

A passive device may include a capacitor and/or a resistor. The various encapsulation layers (e.g., 204, 206) may include a mold, a resin, an epoxy and/or polymer. An encapsulation layer (e.g., 204, 206) may be a means for encapsulation (e.g., first means for encapsulation, second means for encapsulation).

Having described various packages with dummy interconnects, processes for fabricating a package that includes dummy interconnects will now be described below.

### Exemplary Sequence for Fabricating a Packaging Comprising Dummy Interconnects

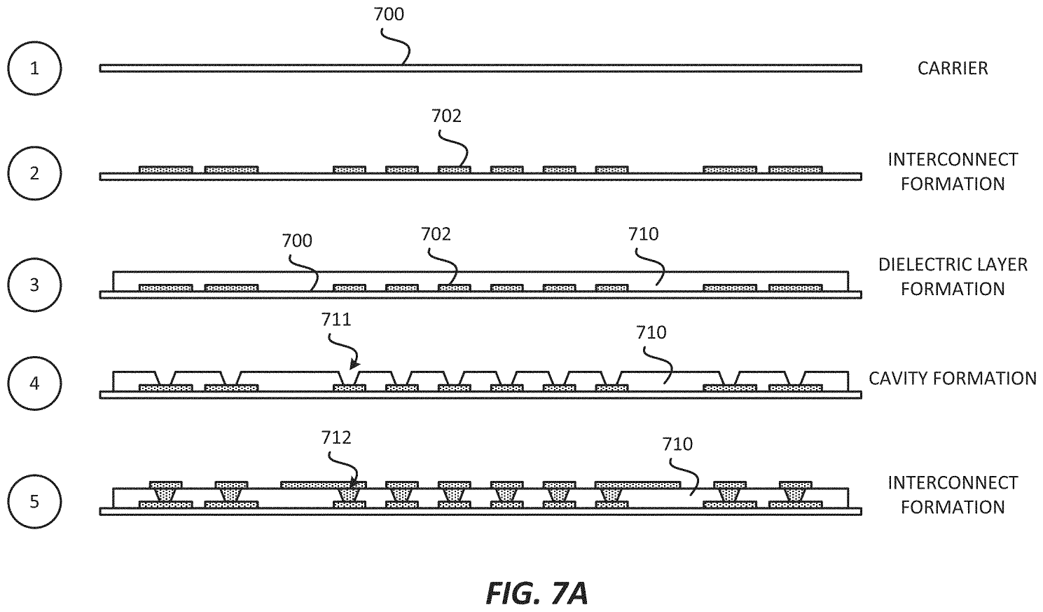

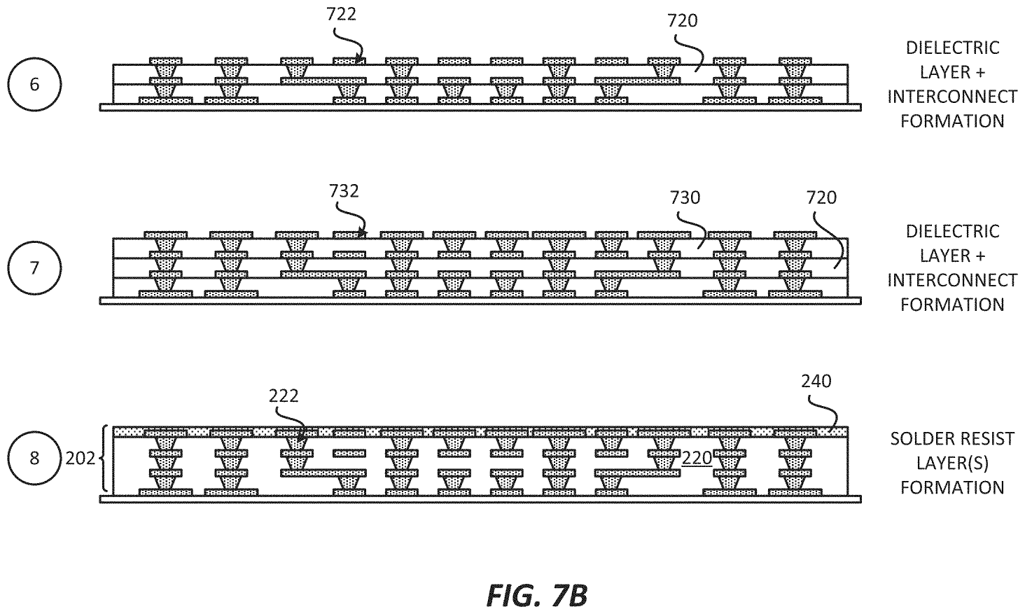

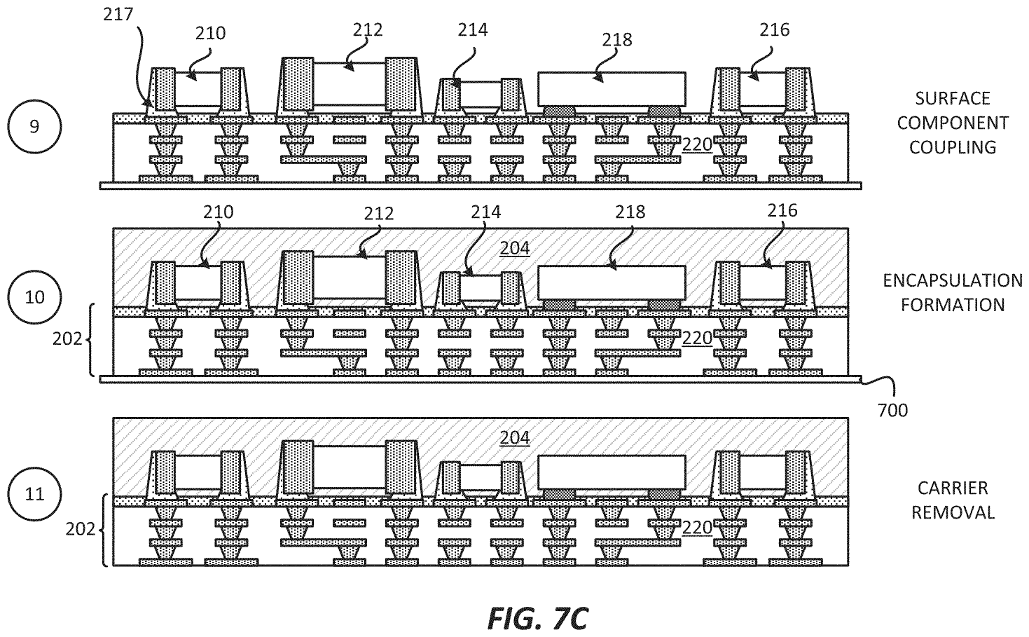

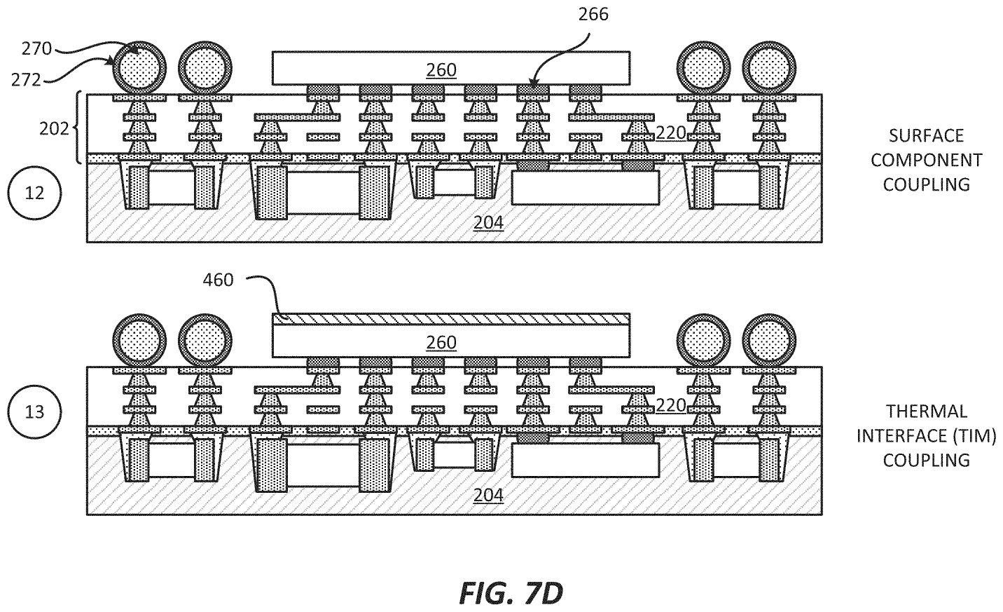

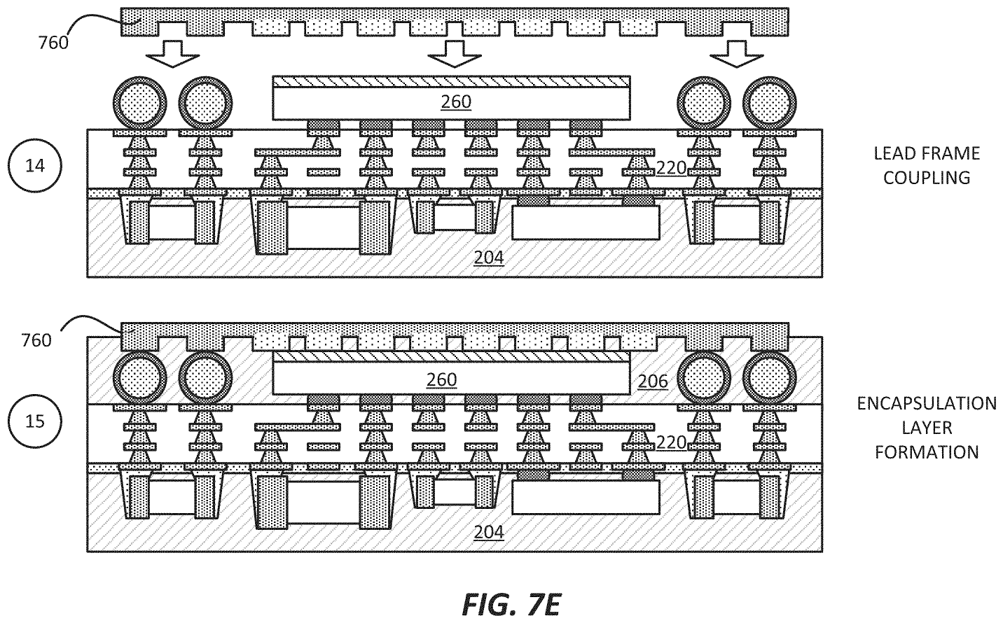

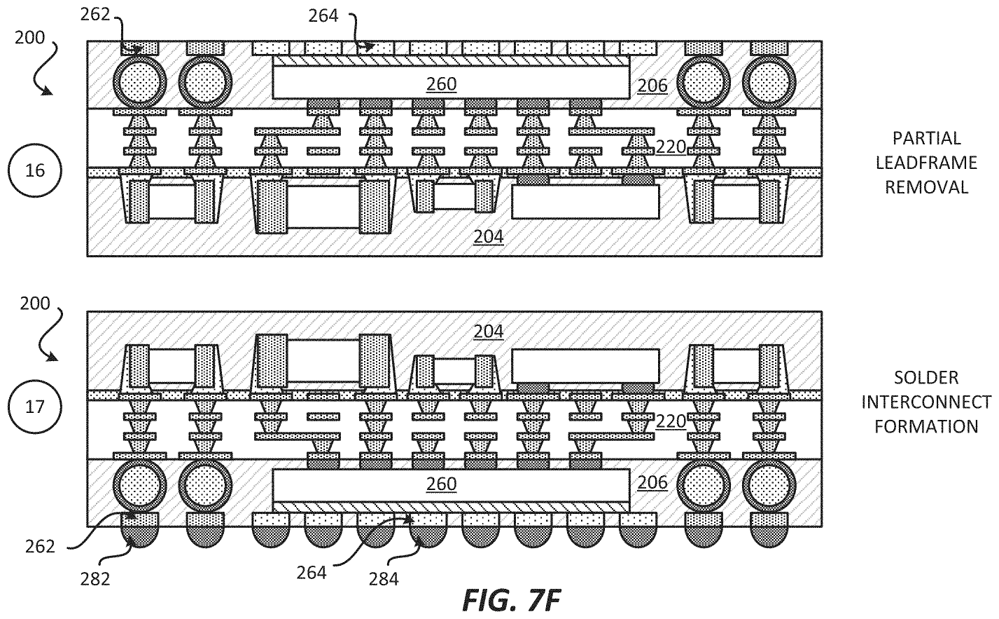

FIG. 7 (which includes FIGS. 7A-7F) illustrates an exemplary sequence for providing or fabricating a package that includes dummy interconnects. In some implementations, the sequence of FIGS. 7A-7F may be used to provide or fabricate the package 200 of FIG. 2, or any of the packages described in the disclosure.

It should be noted that the sequence of FIGS. 7A-7F may combine one or more stages in order to simplify and/or clarify the sequence for providing or fabricating the package. In some implementations, the order of the processes may be changed or modified. In some implementations, one or more of processes may be replaced or substituted without departing from the spirit of the disclosure. Different implementations may fabricate an interconnect structure differently.

Stage 1, as shown in FIG. 7A, illustrates a state after a carrier 700 is provided. The carrier 700 may be a substrate and/or a wafer. The carrier 700 may include glass and/or silicon. The carrier 700 may be a first carrier.

Stage 2 illustrates a state after a plurality of interconnects 702 is formed over the carrier 700. The plurality of interconnects 702 may include traces and/or pads. Forming the plurality of interconnects 702 may include forming a seed layer, performing a lithography process, a plating process, a stripping process and/or an etching process. The plurality of interconnects 702 may be part of the plurality of interconnects 222.

Stage 3 illustrates a state after the dielectric layer 710 is formed over the plurality of interconnects 702 and the carrier 700. The dielectric layer 710 may be deposited and/or coated over the plurality of interconnects 702 and the carrier 700. The dielectric layer 710 may include polymer.

Stage 4 illustrates a state after cavities 711 are formed in the dielectric layer 710. An etching process may be used to form the cavities 711.

Stage 5 illustrates a state after a plurality of interconnects 712 is formed over the dielectric layer 710. The plurality of interconnects 712 may include vias, traces and/or pads. Forming the plurality of interconnects 712 may include forming a seed layer, performing a lithography process, a plating process, a stripping process and/or an etching process. The plurality of interconnects 712 may be part of the plurality of interconnects 222.

Stage 6, as shown in FIG. 7B, illustrates a state after a dielectric layer 720 and a plurality of interconnects 722 are formed over the dielectric layer 710. The dielectric layer 720 may be deposited and/or coated over the plurality of interconnects 712 and the dielectric layer 710. The dielectric layer 720 may include polymer. Forming the dielectric layer 720 may include forming cavities in the dielectric layer 720. An etching process may be used to form the cavities in the dielectric layer 720. The plurality of interconnects 722 may include vias, traces and/or pads. Forming the plurality of interconnects 722 may include forming a seed layer, performing a lithography process, a plating process, a stripping process and/or an etching process. The plurality of interconnects 722 may be part of the plurality of interconnects 222.

Stage 7 illustrates a state after a dielectric layer 730 and a plurality of interconnects 732 are formed over the dielectric layer 720. The dielectric layer 730 may be deposited and/or coated over the plurality of interconnects 722 and the dielectric layer 720. The dielectric layer 730 may include polymer. Forming the dielectric layer 730 may include forming cavities in the dielectric layer 730. An etching process may be used to form the cavities in the dielectric layer 730. The plurality of interconnects 732 may include vias, traces and/or pads. Forming the plurality of interconnects 732 may include forming a seed layer, performing a lithography process, a plating process, a stripping process and/or an etching process. The plurality of interconnects 732 may be part of the plurality of interconnects 222.

Stage 8 illustrates a state after the solder resist layer 240 is formed over the substrate 202. The solder resist layer 240 may be considered part of the substrate 202. The substrate 202 includes the at least one dielectric layer 220 and the plurality of interconnects 222. The at least one dielectric layer 220 may represent the dielectric layers 710, 720 and 730. The plurality of interconnects 222 may represent the plurality of interconnects 712, 722 and 732.

Stage 9, as shown in FIG. 7C, illustrates a state after a plurality of passive devices (e.g., 210, 212, 214, 216) and an integrated device 218 are coupled to a first surface of the substrate 202. A pick and place process may be used to place the passive devices and integrated device over the first surface of the substrate 202. Solder interconnects (e.g., 217) may be used to couple the passive devices (e.g., 210, 212, 214, 216) and the integrated device 218 to the substrate 202 (e.g., interconnects of the substrate 202).

Stage 10 illustrates a state after a first encapsulation layer 204 is formed over the first surface of the substrate 202 such that the first encapsulation layer 204 encapsulates the passive devices (e.g., 210, 212, 214, 216) and the integrated device 218. The process of forming and/or disposing the first encapsulation layer 204 may include using a compression and transfer molding process, a sheet molding process, or a liquid molding process.

Stage 11 illustrates a state after the carrier 700 is decoupled from the substrate 202. The carrier 700 may be decoupled through a grinding process and/or peel off process.

Stage 12, as shown in FIG. 7D, illustrates a state after the integrated device 260 and the plurality of ball interconnects 270 is coupled to a second surface of the substrate 202. The plurality of ball interconnects 270 is coupled to the substrate 202 through the plurality of solder interconnects 272. The integrated device 260 is coupled to the substrate 202 through the plurality of solder interconnects 266. It is noted that in some implementations, instead of the plurality of ball interconnects, the plurality of vias 570 and the dielectric layer 572 may be used instead.

Stage 13, illustrates a state after a thermal interface material (TIM) 460 is formed over the back side of the integrated device 260. The TIM 460 may be optional.

Stage 14, as shown in FIG. 7E, illustrates a state after a lead frame 760 is coupled and/or being coupled to the plurality of ball interconnects 270 and the TIM 460. In some implementations, the lead frame 760 may be coupled directly to the back side of the integrated device 260. A lead frame 760 may include a structure that is electrically conductive. The lead frame 760 may include a unibody or may include several components. The lead frame 760 may be uniform in composition or may include different materials for different portions.

Stage 15 illustrates a state after the second encapsulation layer 206 is formed between the substrate 202 and the lead frame 760. The second encapsulation layer 206 may encapsulate the plurality of ball interconnects 270, the plurality of solder interconnects 272, the integrated device 260, the TIM 460 and/or the lead frame 760. The process of forming and/or disposing the second encapsulation layer 206 may include using a compression and transfer molding process, a sheet molding process, or a liquid molding process.

Stage 16 illustrates a state after portions of the lead frame 760 are removed leaving behind the plurality of encapsulation layer interconnect 262 and the at least one dummy interconnect 264. The at least one dummy interconnect 264 may include the same material or different material than the plurality of encapsulation layer interconnects 262. It is noted that the different shading between the at least one dummy interconnect 264 and the plurality of encapsulation layer interconnects 262 is to help visually distinguish a dummy interconnect from an encapsulation layer interconnect. The difference in shading does not necessarily indicate a difference in materials. A grinding process may be used to remove portions of the lead frame 760. In some implementations, portions of the second encapsulation layer 206 may also be removed to create a flat planar surface with the plurality of encapsulation layer interconnect 262 and the at least one dummy interconnect 264. Stage 16 may illustrate the package 200.

Stage 17 illustrates a state after the plurality of solder interconnects 282 is coupled to the plurality of encapsulation layer interconnects 262, and the plurality of solder interconnects 284 is coupled to the at least one dummy interconnect 264. The plurality of solder interconnects 284 may be a plurality of dummy solder interconnects. Stage 17 may illustrate the package 200 that includes a plurality of dummy interconnects and a plurality of solder dummy interconnects.

### Exemplary Flow Diagram of a Method for Fabricating a Package Comprising Dummy Interconnects

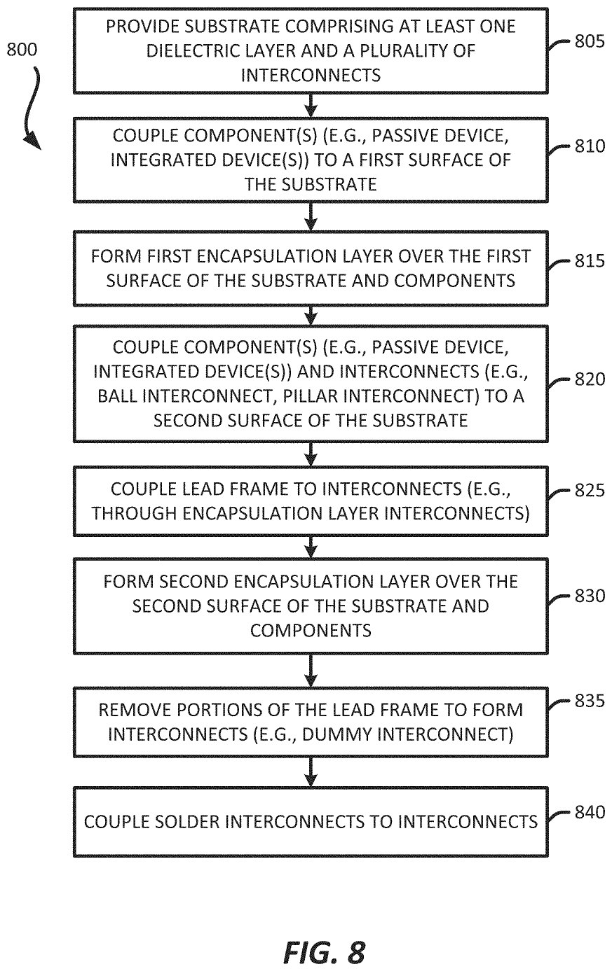

In some implementations, fabricating a package that includes dummy interconnects several processes. FIG. 8 illustrates an exemplary flow diagram of a method 800 for providing or fabricating a package that includes dummy interconnects. In some implementations, the method 800 of FIG. 8 may be used to provide or fabricate the package (e.g., 200) of FIG. 2 described in the disclosure. However, the method 800 may be used to provide or fabricate any of the packages described in the disclosure.

It should be noted that the method of FIG. 8 may combine one or more processes in order to simplify and/or clarify the method for providing or fabricating package. In some implementations, the order of the processes may be changed or modified.

The method provides (at 805) a substrate (e.g., 202) that includes at least one dielectric layer (e.g., 220) and a plurality of interconnects (e.g., 222). The dielectric layer 220 may include polymer. Forming the dielectric layer 220 may include forming cavities in the dielectric layer 220. An etching process may be used to form the cavities in the dielectric layer 220. The plurality of interconnects 222 may include vias, traces and/or pads. Forming the plurality of interconnects 222 may include forming a seed layer, performing a lithography process, a plating process, a stripping process and/or an etching process. Stages 1-8 of FIGS. 7A-7B illustrate an example of providing a substrate.

The method couples (at 810) a plurality of passive devices (e.g., 210, 212, 214, 216) and an integrated device 218 to a first surface of the substrate 202. A pick and place process may be used to place the passive devices and integrated device over the first surface of the substrate 202. Solder interconnects (e.g., 217) may be used to couple the passive devices (e.g., 210, 212, 214, 216) and the integrated device 218 to the substrate 202 (e.g., interconnects of the substrate 202). Stage 9 of FIG. 7C illustrates an example of coupling passive devices to a substrate.

The method forms (at 815) a first encapsulation layer (e.g., 204) over the first surface of the substrate and the components. The first encapsulation layer 204 is formed over the first surface of the substrate 202 such that the first encapsulation layer 204 encapsulates the passive devices (e.g., 210, 212, 214, 216) and the integrated device 218. The process of forming and/or disposing the first encapsulation layer 204 may include using a compression and transfer molding process, a sheet molding process, or a liquid molding process. Stage 10 of FIG. 7C illustrates an example of forming a first encapsulation layer.

The method couples (at 820) components (e.g., integrated device, passive device) and a plurality of through encapsulation layer interconnects (e.g., plurality of ball interconnects 270) to a second surface of the substrate (e.g., 202). The plurality of ball interconnects 270 is coupled to the substrate 202 through the plurality of solder interconnects 272. The integrated device 260 is coupled to the substrate 202 through the plurality of solder interconnects 266. It is noted that in some implementations, instead of the plurality of ball interconnects, the plurality of vias 570 and the dielectric layer 572 may be used instead. Stage 12 of FIG. 7D illustrates an example of components being coupled to a substrate. A TIM (e.g., 460) may also be optionally coupled to the integrated device. In some implementations, the TIM is already coupled to the integrated device when the integrated device is coupled to the substrate. Stage 13 of FIG. 7D illustrates an example of a TIM coupled to an integrated device.

The method couples (at 825) a lead frame (e.g., 760) to the plurality of through encapsulation layer interconnects (e.g., plurality of ball interconnects 270). The lead frame 760 may be coupled to the TIM 460. In some implementations, the lead frame 760 may be coupled directly to the back side of the integrated device 260. A lead frame 760 may include a structure that is electrically conductive. The lead frame 760 may include a unibody or may include several components. The lead frame 760 may be uniform in composition or may include different materials for different portions. Stage 14 of FIG. 7D illustrates an example of a lead frame coupled to interconnects.

The method forms (at 830) a second encapsulation layer (e.g., 206) between the substrate 202 and the lead frame 760. The second encapsulation layer 206 may encapsulate the plurality of through encapsulation layer interconnects (e.g., plurality of ball interconnects 270), the plurality of solder interconnects 272, the integrated device 260, the TIM 460 and/or the lead frame 760. The process of forming and/or disposing the second encapsulation layer 206 may include using a compression and transfer molding process, a sheet molding process, or a liquid molding process.

The method removes (at 835) removes portions of portions of the lead frame 760 are to form the plurality of encapsulation layer interconnect 262 and the at least one dummy interconnect 264. A grinding process may be used to remove portions of the lead frame 760. In some implementations, portions of the second encapsulation layer 206 may also be removed to create a flat planar surface with the plurality of encapsulation layer interconnect 262 and the at least one dummy interconnect 264. Stage 16 of FIG. 7F illustrates an example of a state after portions of the lead frame 760 have been removed.

The method couples (at 840) (i) a plurality of solder interconnects 282 to the plurality of encapsulation layer interconnects 262, and (ii) a plurality of solder interconnects 284 to the at least one dummy interconnect 264. The plurality of solder interconnects 284 may be a plurality of dummy solder interconnects. Stage 17 of FIG. 7F illustrates an example of solder interconnects being coupled to at least one dummy interconnect.

### Exemplary Sequence for Fabricating a Package Comprising Dummy Interconnects

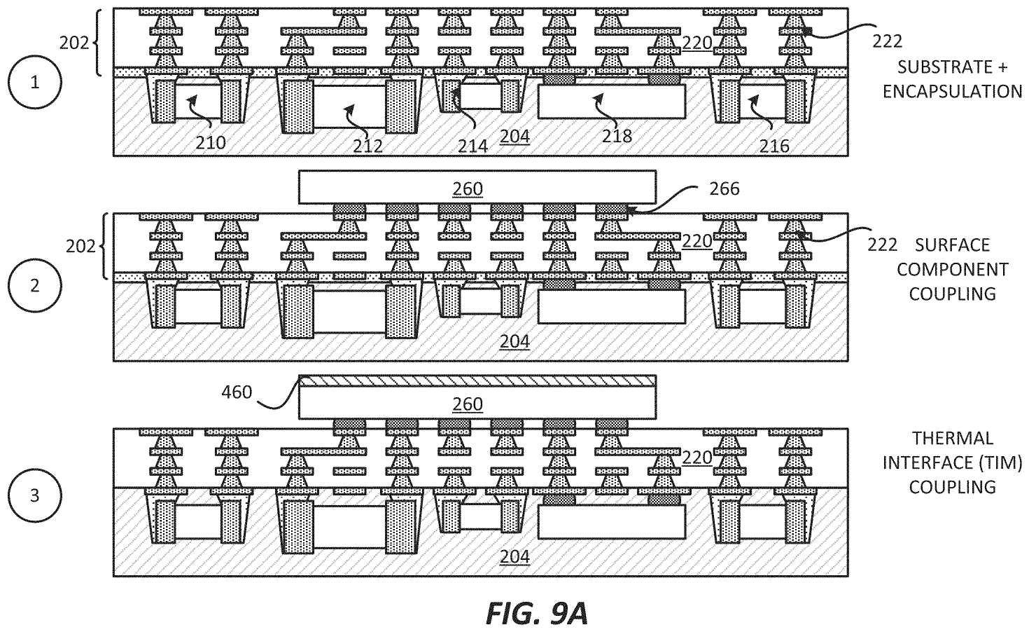

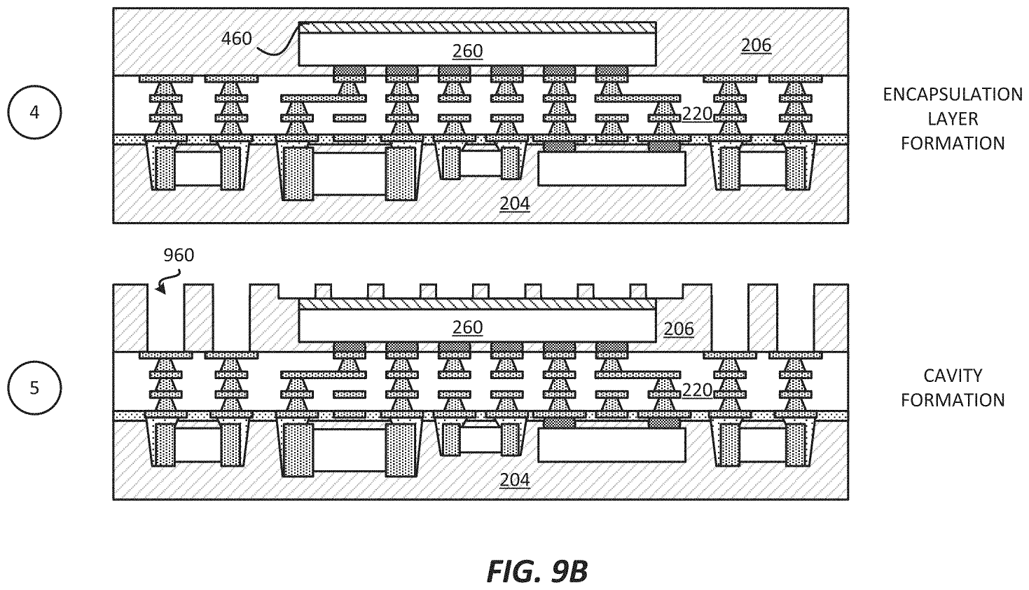

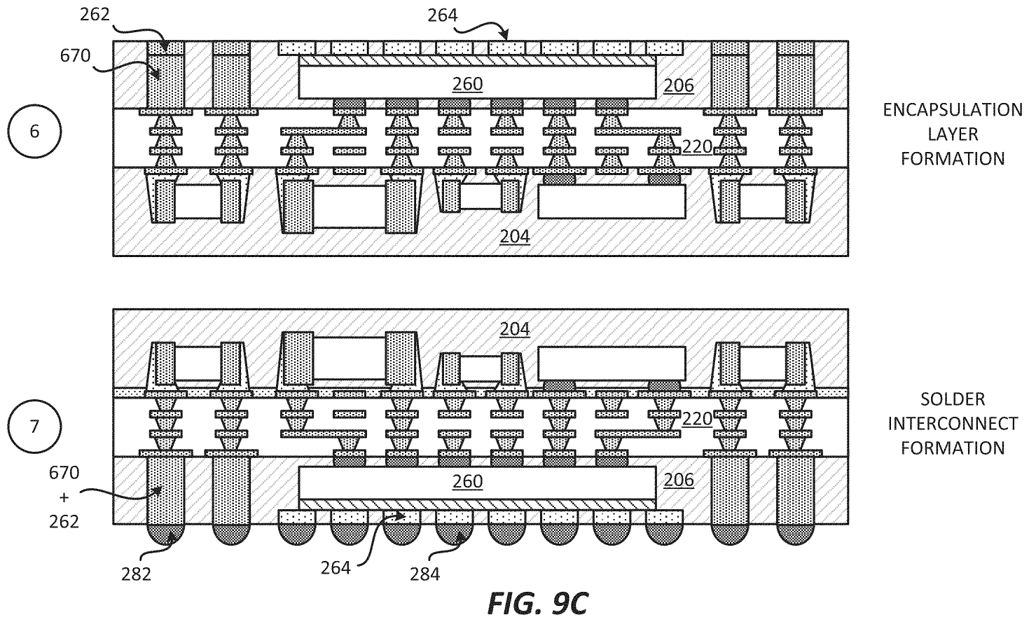

FIG. 9 (which includes FIGS. 9A-9C) illustrates an exemplary sequence for providing or fabricating a package that includes dummy interconnects. In some implementations, the sequence of FIGS. 9A-9C may be used to provide or fabricate the package 600 of FIG. 6, or any of the packages described in the disclosure.

It should be noted that the sequence of FIGS. 9A-9C may combine one or more stages in order to simplify and/or clarify the sequence for providing or fabricating the package. In some implementations, the order of the processes may be changed or modified. In some implementations, one or more of processes may be replaced or substituted without departing from the spirit of the disclosure. Different implementations may fabricate an interconnect structure differently.

Stage 1, as shown in FIG. 9A, illustrates a state after a substrate (e.g., 202), a first encapsulation layer 204, a plurality of passive devices (e.g., 210, 212, 214, 216) and an integrated device 218 are provided. Stage 1 of FIG. 7A may represent Stage 11 of FIG. 7C, and thus may be fabricated in a similar manner as described in Stages 1-11 of FIGS. 7A-7C.

Stage 2 illustrates a state after the integrated device 260 is coupled to a second surface of the substrate 202. The integrated device 260 is coupled to the substrate 202 through the plurality of solder interconnects 266.

Stage 3 illustrates a state after a thermal interface material (TIM) 460 that is formed over the back side of the integrated device 260. The TIM 460 may be optional.

Stage 4, as shown in FIG. 9B, illustrates a state after the second encapsulation layer 206 is formed over the second surface of the substrate 202. The second encapsulation layer 206 may encapsulate the integrated device 260 and the TIM 460. The process of forming and/or disposing the second encapsulation layer 206 may include using a compression and transfer molding process, a sheet molding process, or a liquid molding process.

Stage 5 illustrates a state after cavities 960 are formed in the second encapsulation layer 206. The cavities 960 may be formed over the TIM 460 and/or the back side of the integrated device 260. An etching process (e.g., lithography process) and/or a laser process may be used to form the cavities 960 in the second encapsulation layer.

Stage 6, as shown in FIG. 9C illustrates a state after the plurality of vias 670, the plurality of encapsulation layer interconnects 262 and the at least one dummy interconnect 264 are formed. A plating process and/or a sputtering process may be used to form the plurality of vias 670, the plurality of encapsulation layer interconnects 262 and the at least one dummy interconnect 264. The plurality of vias 670 and the plurality of encapsulation layer interconnects 262 may be considered the same.

Stage 7 illustrates a state after the plurality of solder interconnects 282 is coupled to the plurality of encapsulation layer interconnects 262, and the plurality of solder interconnects 284 is coupled to the at least one dummy interconnect 264. The plurality of solder interconnects 284 may be a plurality of dummy solder interconnects. Stage 7 may illustrate the package 600 that includes a plurality of dummy interconnects and a plurality of solder dummy interconnects.

### Exemplary Flow Diagram of a Method for Fabricating a Package Comprising Dummy Interconnects

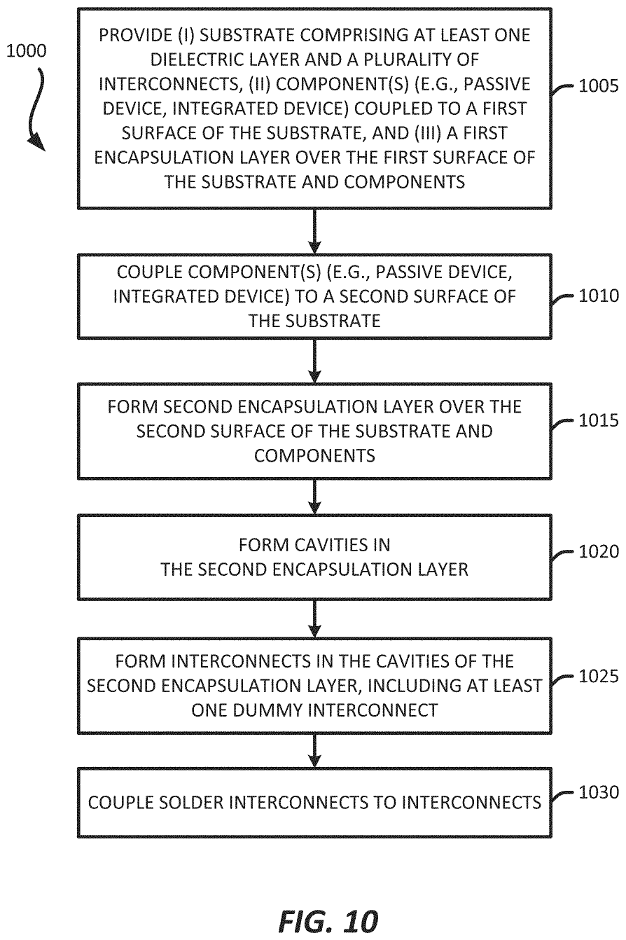

In some implementations, fabricating a package that includes dummy interconnects several processes. FIG. 10 illustrates an exemplary flow diagram of a method 1000 for providing or fabricating a package that includes dummy interconnects. In some implementations, the method 1000 of FIG. 10 may be used to provide or fabricate the package (e.g., 600) of FIG. 6 described in the disclosure. However, the method 1000 may be used to provide or fabricate any of the packages described in the disclosure.

It should be noted that the method of FIG. 10 may combine one or more processes in order to simplify and/or clarify the method for providing or fabricating package. In some implementations, the order of the processes may be changed or modified.

The method provides (at 1005) a substrate (e.g., 202) that includes at least one dielectric layer (e.g., 220), a plurality of interconnects (e.g., 222), a plurality of passive devices (e.g., 210, 212, 214, 216), an integrated device 218, and a first encapsulation layer 204. The dielectric layer 220 may include polymer. Forming the dielectric layer 220 may include forming cavities in the dielectric layer 220. An etching process may be used to form the cavities in the dielectric layer 220. The plurality of interconnects 222 may include vias, traces and/or pads. Forming the plurality of interconnects 222 may include forming a seed layer, performing a lithography process, a plating process, a stripping process and/or an etching process. A pick and place process may be used to place the passive devices and integrated device over the first surface of the substrate 202. Solder interconnects (e.g., 217) may be used to couple the passive devices (e.g., 210, 212, 214, 216) and the integrated device 218 to the substrate 202 (e.g., interconnects of the substrate 202). The first encapsulation layer 204 is formed over the first surface of the substrate 202 such that the first encapsulation layer 204 encapsulates the passive devices (e.g., 210, 212, 214, 216) and the integrated device 218. The process of forming and/or disposing the first encapsulation layer 204 may include using a compression and transfer molding process, a sheet molding process, or a liquid molding process. Stages 1-11 of FIGS. 7A-7C and Stage 1 of FIG. 9A, illustrate examples of providing a substrate, passive devices, an integrated device and an encapsulation layer.

The method couples (at 1010) components (e.g., integrated device, passive device) to a second surface of the substrate (e.g., 202). The integrated device 260 is coupled to the substrate 202 through the plurality of solder interconnects 266. Stage 2 of FIG. 9A illustrates an example of an integrated device coupled to the substrate. A TIM (e.g. 460) may be coupled to the back side of the integrated device. Stage 3 of FIG. 9A illustrates an example of a TIM coupled to a back side of the integrated device.

The method forms (at 1015) a second encapsulation layer (e.g., 206) over the second surface of the substrate 202. The second encapsulation layer 206 may encapsulate the integrated device 260 and the TIM 460. The process of forming and/or disposing the second encapsulation layer 206 may include using a compression and transfer molding process, a sheet molding process, or a liquid molding process. Stage 4 of FIG. 9B illustrates an example of forming a second encapsulation layer.

The method forms (at 1020) cavities (e.g., 960) in the second encapsulation layer 206. The cavities 960 may be formed over the TIM 460 and/or the back side of the integrated device 260. An etching process (e.g., lithography process) and/or a laser process may be used to form the cavities 960 in the second encapsulation layer. Stage 5 of FIG. 9B may illustrates an example of cavities in the second encapsulation layer.

The method forms (at 1025) a plurality of vias 670, a plurality of encapsulation layer interconnects 262 and the at least one dummy interconnect 264 in the cavities (e.g., 960). A plating process and/or a sputtering process may be used to form the plurality of vias 670, the plurality of encapsulation layer interconnects 262 and the at least one dummy interconnect 264. The plurality of vias 670 and the plurality of encapsulation layer interconnects 262 may be considered the same. Stage 6 of FIG. 9C illustrates an example a plurality of vias 670, a plurality of encapsulation layer interconnects 262 and the at least one dummy interconnect 264 in the second encapsulation layer 206.

The method couples (at 1030) (i) a plurality of solder interconnects 282 to the plurality of encapsulation layer interconnects 262, and (ii) a plurality of solder interconnects 284 is coupled to the at least one dummy interconnect 264. The plurality of solder interconnects 284 may be a plurality of dummy solder interconnects. Stage 7 of FIG. 9C may illustrate an example of a plurality of solder dummy interconnects.

### Exemplary Electronic Devices

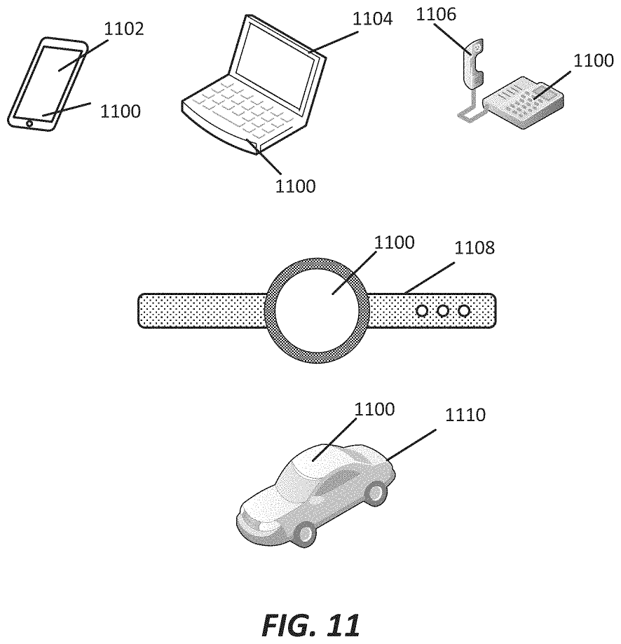

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-6, 7A-7F, 8, 9A-9C, and/or 10-11 may be rearranged and/or combined into a single component, process, feature or function or embodied in several components, processes, or functions. Additional elements, components, processes, and/or functions may also be added without departing from the disclosure. It should also be noted FIGS. 2-6, 7A-7F, 8, 9A-9C, and/or 10-11 and its corresponding description in the present disclosure is not limited to dies and/or ICs. In some implementations, FIGS. 2-6, 7A-7F, 8, 9A-9C, and/or 10-11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The term “encapsulating” means that the object may partially encapsulate or completely encapsulate another object. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. An interconnect may include one or more metal components (e.g., seed layer+metal layer). In some implementations, an interconnect is an electrically conductive material that may be configured to provide an electrical path for a current (e.g., a data signal, ground or power). An interconnect may be part of a circuit. An interconnect may include more than one element or component. An interconnect may be defined by one or more interconnects. Different implementations may use similar or different processes to form the interconnects. In some implementations, a chemical vapor deposition (CVD) process and/or a physical vapor deposition (PVD) process for forming the interconnects. For example, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising a first surface and a second surface, wherein the substrate further comprises a plurality of interconnects;
a passive device coupled to the first surface of the substrate;
a first encapsulation layer located over the first surface of the substrate, wherein the first encapsulation layer encapsulates the passive device;
an integrated device coupled to the second surface of the substrate;
a second encapsulation layer located over the second surface of the substrate, wherein the second encapsulation layer encapsulates the integrated device;
a plurality of through encapsulation layer interconnects coupled to the substrate;
a plurality of encapsulation layer interconnects coupled to the plurality of through encapsulation layer interconnects; and
at least one dummy interconnect located in the second encapsulation layer, wherein the at least one dummy interconnect is located vertically over a back side of the integrated device.

2. The package of claim 1, wherein the at least one dummy interconnect is configured to be free of an electrical connection with the integrated device.

3. The package of claim 1, wherein the at least one dummy interconnect is configured to be free of an electrical connection with the passive device.

4. The package of claim 1, further comprising:
a plurality of solder interconnects coupled to the plurality of encapsulation layer interconnects; and
at least one dummy solder interconnect coupled to the at least one dummy interconnect.

5. The package of claim 1, wherein the plurality of through encapsulation layer interconnects comprises a ball interconnect, a pillar and/or a via.

6. The package of claim 1, further comprising a thermal interface material (TIM) coupled to a back side of the integrated device.

7. The package of claim 1, wherein the thermal interface material (TIM) coupled to the at least one dummy interconnect.

8. The package of claim 1, further comprising a second integrated device coupled to the first surface of the substrate.

9. The package of claim 8, wherein the first encapsulation layer encapsulates the second integrated device.

10. The package of claim 1, wherein the package is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. An apparatus comprising:
a substrate comprising a first surface and a second surface, wherein the substrate further comprises a plurality of interconnects;
a passive device coupled to the first surface of the substrate;
first means for encapsulation located over the first surface of the substrate, wherein the first means for encapsulation encapsulates the passive device;
an integrated device coupled to the second surface of the substrate;
second means for encapsulation located over the second surface of the substrate, wherein the second means for encapsulation encapsulates the integrated device;
a plurality of through encapsulation layer interconnects coupled to the substrate;
a plurality of encapsulation layer interconnects coupled to the plurality of through encapsulation layer interconnects; and
at least one dummy interconnect located in the second means for encapsulation, wherein the at least one dummy interconnect is located vertically over a back side of the integrated device.

12. The apparatus of claim 11, wherein the at least one dummy interconnect is configured to be free of an electrical connection with the integrated device.

13. The apparatus of claim 11, wherein the at least one dummy interconnect is configured to be free of an electrical connection with the passive device.

14. The apparatus of claim 11, further comprising:
a plurality solder interconnects coupled to the plurality of encapsulation layer interconnects; and
at least one dummy solder interconnect coupled to the at least one dummy interconnect.

15. The apparatus of claim 11, wherein the plurality of through encapsulation layer interconnects comprises a ball interconnect, a pillar and/or a via.

16. The apparatus of claim 11, further comprising a thermal interface material (TIM) coupled to a back side of the integrated device.

17. The apparatus of claim 11, wherein the thermal interface material (TIM) coupled to the at least one dummy interconnect.

18. The apparatus of claim 11, further comprising a second integrated device coupled to the first surface of the substrate.

19. The apparatus of claim 18, wherein the first means for encapsulation encapsulates the second integrated device.

20. The apparatus of claim 11, wherein the apparatus is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating a package, comprising:
providing a substrate comprising a first surface and a second surface, wherein the substrate further comprises a plurality of interconnects;
coupling a passive device to the first surface of the substrate;
forming a first encapsulation layer over the first surface of the substrate, wherein the first encapsulation layer encapsulates the passive device;
coupling an integrated device to the second surface of the substrate;
providing a plurality of through encapsulation layer interconnects to the substrate;
forming a second encapsulation layer over the second surface of the substrate, wherein the second encapsulation layer encapsulates the integrated device;
providing a plurality of encapsulation layer interconnects to the plurality of through encapsulation layer interconnects; and
providing at least one dummy interconnect in the second encapsulation layer, wherein the at least one dummy interconnect is located vertically over a back side of the integrated device.

22. The method of claim 21, wherein the at least one dummy interconnect is configured to be free of an electrical connection with the integrated device.

23. The method of claim 21, wherein the at least one dummy interconnect is configured to be free of an electrical connection with the passive device.
